(19) United States
(12) Patent Application Publication
(10) Pub. No.: US 2026/0031304 A1
(43) Pub. Date: Jan. 29, 2026

(54) SHOWER HEAD ASSEMBLY AND SEMICONDUCTOR MANUFACTURING EQUIPMENT INCLUDING THE SAME

(71) Applicant: SAMSUNG ELECTRONICS CO., LTD., Suwon-si (KR)

(72) Inventors: Seongjun Doh, Suwon-si (KR); Jaebin Kim, Suwon-si (KR); Jaesung Kim, Suwon-si (KR); Jong In Park, Suwon-si (KR); Haeyoon Choi, Suwon-si (KR); Dongyeon Han, Suwon-si (KR); Sang-Ho Lee, Suwon-si (KR); Kangmin Jeon, Suwon-si (KR); Seongha Jeong, Suwon-si (KR)

(73) Assignee: SAMSUNG ELECTRONICS CO., LTD., Suwon-si (KR)

(21) Appl. No.: 19/219,514

(22) Filed: May 27, 2025

(30) Foreign Application Priority Data
Jul. 29, 2024 (KR) 10-2024-0100511

(51) Int. Cl. H01J 37/32

(52) U.S. Cl. CPC H01J 37/3244; H01J 37/32522; H01J 37/32357; H01J 2237/002

(57) ABSTRACT

A shower head assembly includes: a first plate including a first gas hole; a second plate including a second gas hole that is fluidly coupled to the first gas hole; and a thermal conductive pad between the first plate and the second plate, the thermal conductive pad including a first opening that fluidly couples the first gas hole to the second gas hole, wherein the first opening has a diameter greater than at least one from among a diameter of the first gas hole and a diameter of the second gas hole.

### CROSS-REFERENCE TO RELATED APPLICATION

This application claims priority to and the benefit of Korean Patent Application No. 10-2024-0100511, filed on Jul. 29, 2024, in the Korean Intellectual Property Office, the disclosure of which is incorporated by reference herein in its entirety.

### BACKGROUND

### 1. Field

Embodiments of the present disclosure relate to semiconductor manufacturing equipment.

### 2. Brief Description of Background Art

In general, a series of processes, such as deposition, etching, and cleaning, may be performed to manufacture a semiconductor device. These processes may be carried out using a deposition device, an etching device, and a cleaning device equipped with a process chamber.

The process chamber, which provides a space for wafer processing, may include a thermal conductive pad. The thermal conductive pad may be placed between two solid plates and increases the contact area between the two solid plates to improve heat transfer performance.

### SUMMARY

According to some embodiments of the present disclosure, a thermal conductive pad may be provided that prevents a gas hole from being blocked due to a displacement of the thermal conductive pad in a high-temperature process.

According to some embodiments of the present disclosure, a shower head assembly may be provided and include: a first plate including a first gas hole; a second plate including a second gas hole that is fluidly coupled to the first gas hole; and a thermal conductive pad between the first plate and the second plate, the thermal conductive pad including a first opening that fluidly couples the first gas hole to the second gas hole, wherein the first opening has a diameter greater than at least one from among a diameter of the first gas hole and a diameter of the second gas hole.

According to some embodiments of the present disclosure, a shower head assembly may be provided and include: a lower shower head; and an upper shower head on the lower shower head, the lower shower head including: a lower plate including lower plate gas holes; and a support column extending upward from an upper surface of the lower plate and coupled to the upper shower head, wherein the lower plate includes: a first plate including first gas holes; a second plate including second gas holes that are fluidly coupled to the first gas holes, respectively; and a thermal conductive pad between the first plate and the second plate, the thermal conductive pad including openings that fluidly couples the first gas holes to the second gas holes, respectively, wherein each opening from among the openings has a diameter greater than a diameter of at least one from among a corresponding one of the first gas holes that is fluidly coupled to the opening and a corresponding one of the second gas holes that is fluidly coupled to the opening.

According to some embodiments of the present disclosure, semiconductor manufacturing equipment may be provided and include: a shower head assembly including an upper shower head and a lower shower head, the lower shower head including: a first plate including first gas holes; a second plate including second gas holes that are fluidly coupled to the first gas holes, respectively; and a thermal conductive pad between the first plate and the second plate, the thermal conductive pad including openings that fluidly couple the first gas holes to the second gas holes, respectively, wherein each opening from among the openings has a diameter greater than a diameter at least one from among a corresponding first gas hole from among the first gas holes that is fluidly coupled to the opening and a corresponding second gas hole from among the second gas holes that is fluidly coupled to the opening.

Due to the thermal conductive pad according to some embodiments of the present disclosure, a gas hole blockage caused by a displacement of the thermal conductive pad in high-temperature process may be prevented.

### BRIEF DESCRIPTION OF DRAWINGS

The above and other aspects and features of embodiments of the present disclosure will become apparent by describing in detail non-limiting example embodiments thereof with reference to the accompanying drawings.

FIG. 1 is a view illustrating semiconductor manufacturing equipment according to an embodiment of the present disclosure;

FIG. 2 is an enlarged cross-sectional view illustrating an area A of FIG. 1 according to an embodiment of the present disclosure;

FIG. 3 is a cross-sectional view illustrating a shower head assembly according to an embodiment of the present disclosure;

FIG. 4A is a view illustrating a pad displacement phenomenon caused by a high-temperature process;

FIG. 4B is a view illustrating a gas hole blockage phenomenon due to the pad displacement phenomenon;

FIGS. 5A and 5B are views illustrating an opening of a thermal conductive pad according to an embodiment of the present disclosure;

FIG. 6 is a plan view illustrating a thermal conductive pad according to an embodiment of the present disclosure;

FIGS. 7A to 7C are views illustrating an opening of an area A1 of FIG. 6;

FIGS. 8 to 10 are plan views illustrating thermal conductive pads according to embodiments of the present disclosure;

FIG. 11 is a view illustrating semiconductor manufacturing equipment according to an embodiment of the present disclosure;

FIG. 12A is an enlarged cross-sectional view illustrating an area E of FIG. 11 according to an embodiment of the present disclosure; and

FIG. 12B is an enlarged cross-sectional view illustrating an area F of FIG. 11 according to an embodiment of the present disclosure.

### DETAILED DESCRIPTION

Below, non-limiting example embodiments of the present disclosure will be described in detail and clearly to such an extent that an ordinary one in the art easily implements embodiments of the present disclosure. Hereinafter, a first direction D1, a second direction D2 intersecting the first direction D1, and a third direction D3 intersecting each of the first direction D1 and the second direction D2 are described. The first direction D1 may also be referred to as a vertical direction. Each of the second direction D2 and the third direction D3 may be referred to as a horizontal direction.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

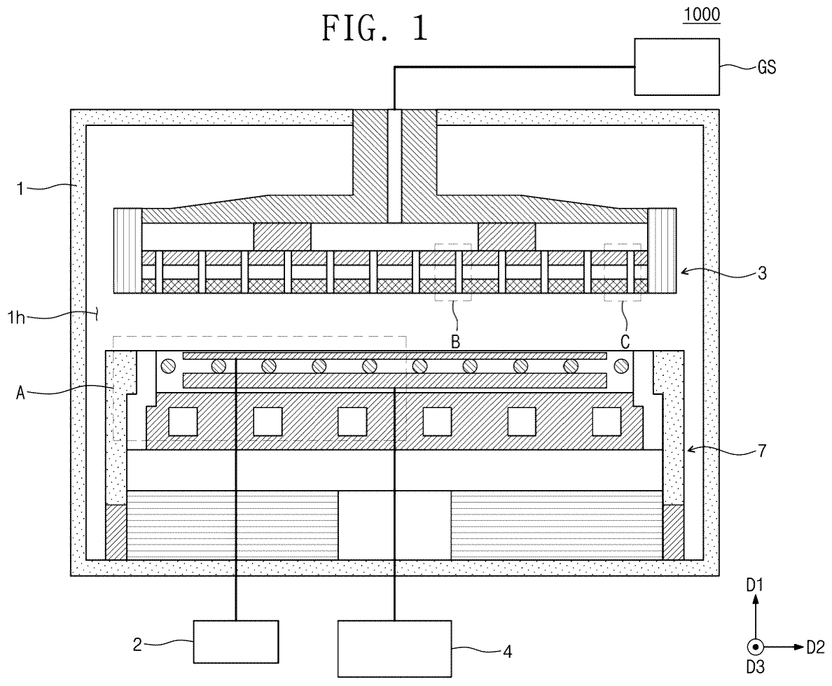

FIG. 1 is a view illustrating semiconductor manufacturing equipment 1000 according to an embodiment of the present disclosure.

The semiconductor manufacturing equipment 1000 according to an embodiment of the present disclosure may include a process chamber 1, and the process chamber 1 may include a thermal conductive pad. As an example, the thermal conductive pad may have flexibility and may be disposed between a first plate and a second plate, which may be formed of a solid material. Accordingly, a contact area between the first plate and the second plate may increase, and a heat transfer performance between the first plate and the second plate may be improved.

In addition, the first plate may be provided with a plurality of first gas holes defined therethrough, the second plate may be provided with a plurality of second gas holes defined therethrough, and the thermal conductive pad may be provided with a plurality of openings that fluidly couples the first gas holes to the second gas holes. In this case, according to the present embodiment, the opening of the thermal conductive pad may have a diameter greater than a diameter of the first gas hole and/or a diameter of the second gas hole. Therefore, a phenomenon in which the gas holes are blocked (hereinafter, referred to as a gas hole blockage phenomenon) due to a displacement of the pad caused by a high-temperature process may be prevented from occurring.

Referring to FIG. 1, the semiconductor manufacturing equipment 1000 may be provided. The semiconductor manufacturing equipment 1000 may process a wafer using fluid. As an example, the semiconductor manufacturing equipment 1000 may perform a process of forming a thin layer on the wafer.

According to an embodiment, the semiconductor manufacturing equipment 1000 may process the wafer using plasma. To this end, the semiconductor manufacturing equipment 1000 may generate plasma in a variety of ways. As an example, the semiconductor manufacturing equipment 1000 may generate plasma using a capacitive coupled plasma (CCP) method. However, this is merely an example. According to an embodiment, the semiconductor manufacturing equipment 1000 may generate plasma using an inductively coupled plasma (ICP) method, a microwave method, etc.

According to an embodiment, the semiconductor manufacturing equipment 1000 may perform a chemical vapor deposition (CVD) process on the wafer. Further, the semiconductor manufacturing equipment 1000 may perform various deposition processes and/or etching processes on the wafer. In the following descriptions, for the convenience of explanation, it is assumed that the semiconductor manufacturing equipment 1000 generates plasma using the capacitive coupled plasma (CCP) method.

The semiconductor manufacturing equipment 1000 may include the process chamber 1, a stage 7, a shower head assembly 3, a direct current (DC) power generator 2, a radio-frequency (RF) power generator 4, a vacuum pump, and a gas supply unit GS (e.g., a gas supply).

The process chamber 1 may provide a process space 1h. Processes on the wafer may be performed in the process space 1h. The process space 1h may be isolated from an outside of the process chamber 1. During the processes on the wafer, the process space 1h may be substantially in a vacuum state.

The process chamber 1 may have, for example, a cylindrical shape. However, this is merely an example. According to an embodiment, the process chamber 1 may be implemented in a variety of shapes.

The stage 7 may be placed in the process chamber 1. That is, the stage 7 may be placed in the process space 1h. The stage 7 may support and hold the wafer. The processes may be performed on the wafer while the wafer is seated on the stage 7.

The shower head assembly 3 may be placed in the process chamber 1. That is, the shower head assembly 3 may be placed in the process space 1h. The shower head assembly 3 may be placed spaced apart from the stage 7 in the first direction D1. Gases provided from the gas supply unit GS may be uniformly sprayed to the process space 1h through the shower head assembly 3.

The shower head assembly 3 may include the thermal conductive pad. In this case, the thermal conductive pad may include the openings, and the openings may be formed spaced apart from each other in the horizontal direction. Each of the openings may be fluidly coupled to a corresponding gas hole among the gas holes. In the present disclosure, “fluidly coupled” means that components are coupled to each other in a way that allows fluid to move between them, and this may include both direct and indirect connection. As an example, a third component may be disposed between first and second components that are fluidly coupled to each other.

According to an embodiment of the present disclosure, the diameter of the opening of the thermal conductive pad may be greater than the diameter of the corresponding gas hole. For instance, when the thermal conductive pad is disposed between the first plate and the second plate, the opening of the thermal conductive pad may be greater than the corresponding gas hole of the first plate and/or the corresponding gas hole of the second plate. Accordingly, the gas hole blockage phenomenon caused by the pad displacement in the high-temperature process may be prevented.

According to an embodiment, among the openings of the thermal conductive pad, a first opening may have a diameter different from a diameter of the second opening. As an example, the diameter of the second opening adjacent to an edge of the thermal conductive pad may be greater than the diameter of the first opening adjacent to a center of the thermal conductive pad. Accordingly, the deterioration in the heat transfer performance may be reduced, and the gas hole blockage phenomenon caused by the pad displacement may be prevented.

Referring to FIG. 1, the DC power generator 2 may supply a DC power to the stage 7. The wafer may be fixed to a certain position on the stage 7 by the DC power supplied by the DC power generator 2.

The RF power generator 4 may supply an RF power to the stage 7. Thus, the plasma in the process space 1h may be controlled.

The vacuum pump may be connected to the process space 1h. The process space 1h may be maintained substantially in the vacuum state by the vacuum pump while the processes on the wafer are in progress.

The gas supply unit GS may supply gases to the process space 1h. To this end, the gas supply unit GS may include a gas tank, a compressor, a valve, etc. A portion of the gas supplied to the process space 1h by the gas supply unit GS may become the plasma.

As described above, the semiconductor manufacturing equipment 1000 according to an embodiment of the present disclosure may include the thermal conductive pad, and the diameter of the opening of the thermal conductive pad may be greater than the diameter of the gas hole of the plate. Therefore, the pad displacement caused by the high-temperature process and the gas hole blockage phenomenon due to the pad displacement may be prevented.

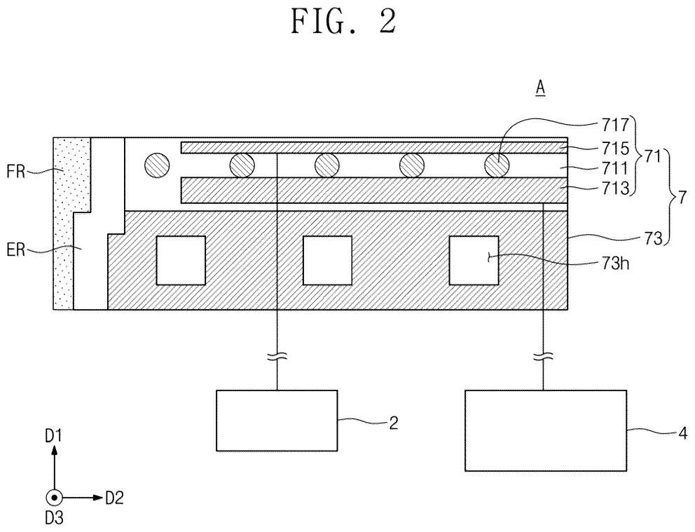

FIG. 2 is an enlarged cross-sectional view illustrating an area A of FIG. 1 according to an embodiment of the present disclosure.

Referring to FIG. 2, the stage 7 may include a chuck 71 and a cooling plate 73.

The wafer may be placed on the chuck 71. The chuck 71 may fix the wafer to the certain position. To this end, the chuck 71 may include a chuck body 711, a plasma electrode 713, a chuck electrode 715, and a heater 717.

The chuck body 711 may have, for example, a cylindrical shape. The chuck body 711 may include a ceramic material. However, embodiments of the present disclosure are not limited thereto or thereby. The wafer may be disposed on an upper surface of the chuck body 711. A focus ring FR and/or an edge ring ER may surround the chuck body 711.

The plasma electrode 713 may be placed in the chuck body 711. The plasma electrode 713 may include aluminum (Al). However, embodiments of the present disclosure are not limited to thereto or thereby. In addition, the plasma electrode 713 may have a disc shape. However, embodiments of the present disclosure are not limited to thereto or thereby.

The RF power may be applied to the plasma electrode 713. As an example, the RF power generator 4 may apply the RF power to the plasma electrode 713. In this case, the plasma in the process space 1h (refer to FIG. 1) may be controlled by the RF power applied to the plasma electrode 713.

The chuck electrode 715 may be placed in the chuck body 711. As an example, the chuck electrode 715 may be placed above the plasma electrode 713. The chuck electrode 715 may include aluminum (Al). However, embodiments of the present disclosure are not limited to thereto or thereby.

The DC power may be applied to the chuck electrode 715. As an example, the DC power generator 2 may apply the DC power to the chuck electrode 715. The wafer may be fixed to the certain position on the chuck body 711 by the DC power applied to the chuck electrode 715.

The heater 717 may be placed in the chuck body 711. The heater 717 may be disposed between the chuck electrode 715 and the plasma electrode 713.

The heater 717 may include a heating coil. As an example, the heater 717 may include a heating coil in a concentric form. The heater 717 may discharge heat to its surroundings. Accordingly, a temperature of the chuck body 711 may increase.

The cooling plate 73 may be placed under the chuck 71. That is, the chuck 71 may be placed on the cooling plate 73. The cooling plate 73 may include a cooling hole 73h, and a coolant may flow through the cooling hole 73h. The coolant in the cooling hole 73h may absorb the heat from the cooling plate 73.

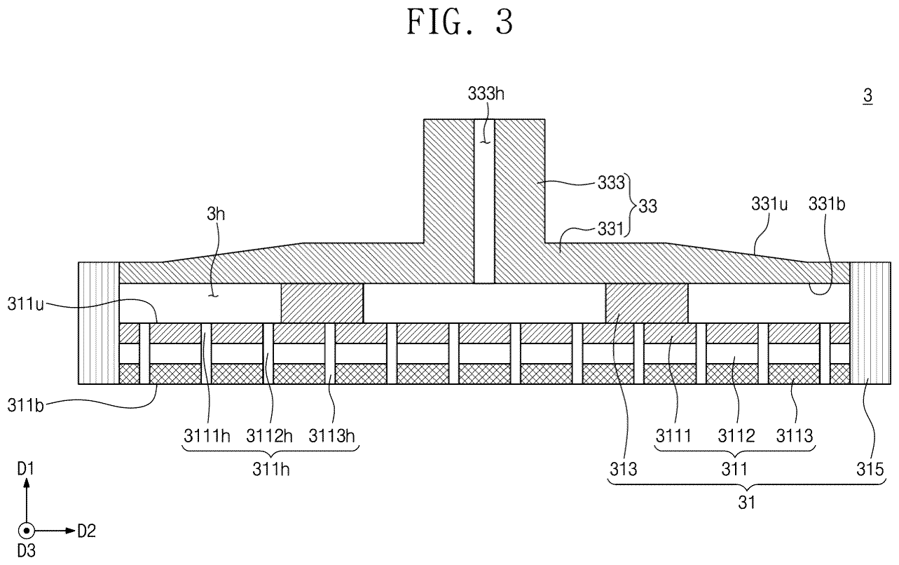

FIG. 3 is a cross-sectional view illustrating the shower head assembly 3 according to an embodiment of the present disclosure.

Referring to FIG. 3, the shower head assembly 3 may include a lower shower head 31 and an upper shower head 33.

The lower shower head 31 may be placed under the upper shower head 33 and may spray the gas supplied thereto via the upper shower head 33 to the process space 1h (refer to FIG. 1) via a plurality of gas holes 311h. The lower shower head 31 may include a lower plate 311, a support column 313, and an edge coupling ring 315.

The lower plate 311 may provide at least one gas hole 311h. As an example, the lower plate 311 may provide a plurality of the gas holes 311h, and the gas holes 311h may be spaced apart from each other in a horizontal direction(s). The gas hole 311h may penetrate through the lower plate 311. As an example, the gas hole(s) 311h may penetrate through the lower plate 311 in the vertical direction. Accordingly, the gas hole(s) 311h may penetrate the lower plate 311 from an upper surface 311u of the lower plate 311 to a lower surface 311b of the lower plate 311. However, this is merely an example. According to an embodiment, the gas holes 311h may be inclined at a predetermined angle with respect to the first direction D1 while penetrating through the lower plate 311.

The lower surface 311b and/or the upper surface 311u of the lower plate 311 may have a flat shape. Therefore, the lower plate 311 may have a uniform thickness. However, this is merely an example, and embodiments of the present disclosure are not limited thereto or thereby.

The support column 313 may be coupled to the lower plate 311. As an example, the support column 313 may extend upward from the upper surface 311u of the lower plate 311. The support column 313 may be formed integrally with the lower plate 311, but embodiments of the present disclosure are not limited thereto or thereby.

The support column 313 may be coupled to the upper shower head 33. As an example, an upper end of the support column 313 may extend above a lower surface 331b of an upper plate 331, and thus, a portion of the support column 313 may be embedded into the inside of the upper plate 331. The support column 313 may be coupled to the upper shower head 33 by welding or other methods. The support column 313 may include, for example, aluminum (Al). However, embodiments of the present disclosure are not limited thereto or thereby.

The edge coupling ring 315 may extend upward from an edge of the lower plate 311. The edge coupling ring 315 may be formed integrally with the lower plate 311. The edge coupling ring 315 may be coupled to the upper shower head 33. As an example, the edge coupling ring 315 may be coupled to an edge of the upper plate 331. The edge coupling ring 315 may be fixedly coupled to the upper plate 331 by welding or other methods. The edge coupling ring 315 may include, for example, aluminum (Al). However, embodiments of the present disclosure are not limited thereto or thereby.

The upper shower head 33 may be placed on the lower shower head 31. The upper shower head 33 may be coupled to an upper side of the lower shower head 31. The upper shower head 33 may receive the gas through the gas supply unit GS (refer FIG. 1) and may provide the gas to a distribution space 3h. The upper shower head 33 may include the upper plate 331 and a support member 333.

The upper plate 331 may be spaced apart upward from the lower plate 311. The distribution space 3h may be provided between the upper plate 331 and the lower plate 311. As an example, the distribution space 3h may be provided between the lower surface 331b of the upper plate 331 and the upper surface 311u of the lower plate 311. The distribution space 3h may be connected to the gas hole 311h. The lower surface 331b of the upper plate 331 may be flat. However, embodiments of the present disclosure are not limited thereto or thereby. The upper plate 331 may include portions where a thickness in the vertical direction increases toward an inner side thereof in the horizontal direction.

The support member 333 may extend upward from the upper plate 331. The support member 333 may provide a gas transmission passage 333h. The gas transmission passage 333h may vertically penetrate through the support member 333. The gas transmission passage 333h may be connected to the distribution space 3h. The gas transmission passage 333h may be connected to the gas supply unit GS, and the gas provided from the gas supply unit GS may flow in the distribution space 3h via the gas transmission passage 333h. The gas that enters the distribution space 3h may flow to the process space 1h through the gas holes 311h.

According to an embodiment, the shower head assembly 3 may include the thermal conductive pad 3112. As an example, the thermal conductive pad 3112 may have flexibility and may be disposed between the first plate 3111 and the second plate 3113, which may be solid plates. The thermal conductive pad 3112 may increase the contact area between the first plate 3111 and the second plate 3113, and thus, the heat transfer performance between the first plate 3111 and the second plate 3113 may be improved.

Hereinafter, for the convenience of explanation, the first plate 3111 may be referred to as a temperature control plate, and the second plate 3113 may be referred to as a shower head electrode. In this case, the lower plate 311 may include the first plate 3111, the thermal conductive pad 3112, and the second plate 3113, and the thermal conductive pad 3112 may be disposed between the first plate 3111 and the second plate 3113.

The first plate 3111 may be provided to control a temperature of the second plate 3113. As an example, the first plate 3111 may be a cooling plate, a heating plate, or a combination of the cooling plate and the heating plate.

As an example, when the first plate 3111 is the cooling plate, the first plate 3111 may be provided with a cooling hole defined therethrough to allow a coolant to flow. Accordingly, during the process, excess heat from the second plate 3113 may be removed.

As an example, when the first plate 3111 is the heating plate, the first plate 3111 may include a heat pipe. Therefore, during the process, heat may be transmitted to the second plate 3113.

The first plate 3111 may be formed of, for example, a non-ductile solid or a solid with low ductility. As an example, the first plate 3111 may include aluminum. However, embodiments of the present disclosure are not limited thereto or thereby.

The thermal conductive pad 3112 may be disposed between the first plate 3111 and the second plate 3113. As an example, the thermal conductive pad 3112 may be formed to have ductility and may be disposed between the first plate 3111 and the second plate 3113, which may be non-ductile or have low ductility. Accordingly, the contact area between the first plate 3111 and the second plate 3113 may increase, and the heat transfer performance between the first plate 3111 and the second plate 3113 may be improved.

The thermal conductive pad 3112 may include, for example, carbon and aluminum. However, this is merely an example, and embodiments of the present disclosure are not limited thereto or thereby.

The second plate 3113 may be provided to perform a plasma process on the wafer. As an example, the RF power may be applied to the second plate 3113 and the plasma electrode 713 (refer to FIG. 2), and thus, the plasma may be generated by the process space 1h.

The second plate 3113 may include, for example, silicon. However, this is merely an example, and embodiments of the present disclosure are not limited thereto or thereby. In addition, the second plate 3113 may have the disc shape to perform the plasma process on the wafer having a circular shape. However, embodiments of the present disclosure are not limited thereto or thereby.

According to an embodiment, the gas holes 311h of the lower plate 311 may include a first gas hole 3111h, an opening 3112h, and a second gas hole 3113h. As an example, the first gas hole 3111h may be provided in plural through the first plate 3111, the second gas hole 3113h may be provided in plural through the second plate 3113, and the opening 3112h may be provided in plural through the thermal conductive pad 3112 to fluidly couple the first gas holes 3111h with the second gas holes 3113h.

According to the present embodiment, the diameter of the opening 3112h of the thermal conductive pad 3112 may be greater than the diameter of the first gas hole 3111h and/or the diameter of the second gas hole 3113h. Accordingly, a phenomenon in which the pad is displaced (hereinafter, referred to as a pad displacement phenomenon) due to the high-temperature process and the gas hole blockage phenomenon caused by the pad displacement phenomenon may be prevented.

According to an embodiment, among the openings 3112h of the thermal conductive pad 3112, the first opening may have the diameter different from the diameter of the second opening. As an example, the opening 3112h of the thermal conductive pad 3112 may have an increasing diameter as a distance from a center of the thermal conductive pad 3112 increases along the horizontal direction. Accordingly, the gas hole blockage phenomenon caused by the pad displacement phenomenon in the high-temperature process may be prevented, and deterioration of the heat transfer performance may be reduced.

According to an embodiment, some of the openings 3112h of the thermal conductive pad 3112 may have an oval shape, and a diameter of a major axis of the oval shape may increase as a distance from the center of the thermal conductive pad 3112 increases along the horizontal direction.

As described above, as the diameter of the opening 3112h of the thermal conductive pad 3112 is greater than a diameter of the corresponding one of the first gas hole 3111h or the second gas hole 3113h, the gas hole blockage phenomenon caused by the pad displacement phenomenon in the high-temperature process may be prevented.

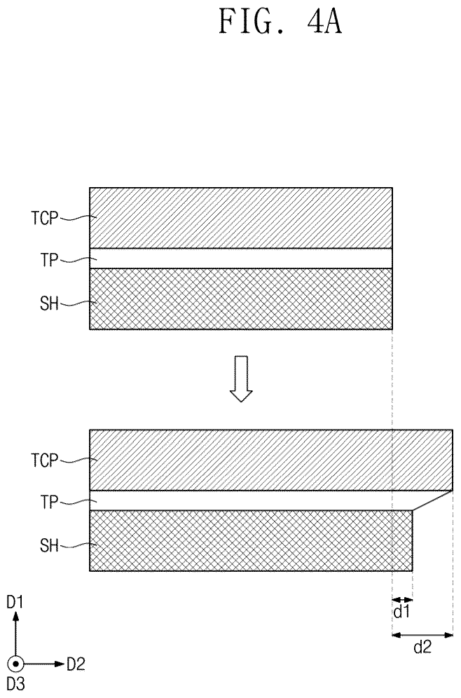

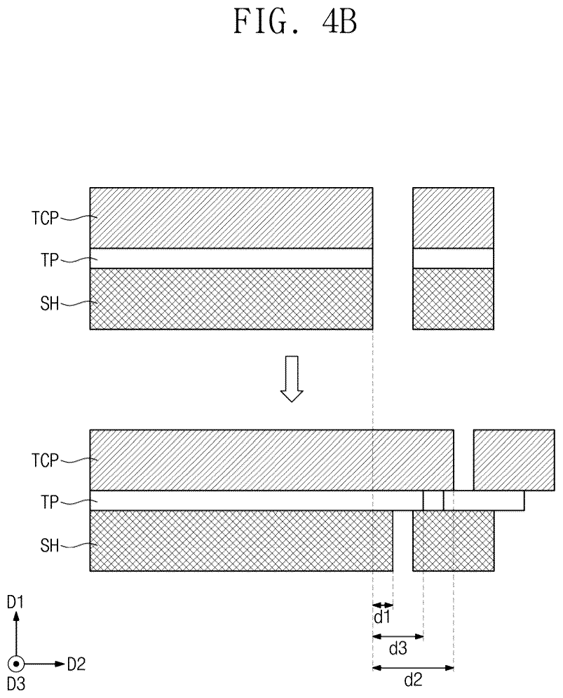

FIGS. 4A and 4B are views illustrating a pad displacement phenomenon caused by a high-temperature process and a gas blockage phenomenon due to the pad displacement phenomenon. For the convenience of explanation, it is assumed that a first plate is a temperature control plate, a second plate is a shower head electrode, and a thermal conductive pad is disposed between the temperature control plate and the shower head electrode.

Referring to FIG. 4A, a temperature of the shower head electrode SH may be maintained at high temperature (e.g., about 165 Celsius degrees or more) during the process. Since the thermal conductive pad TP is mounted at room temperature, the shower head electrode SH, the thermal conductive pad TP, and the temperature control plate TCP may experience a large temperature difference (e.g., about 140 Celsius degrees or more) due to the high-temperature process. Since the temperature control plate TCP has a thermal expansion coefficient different from a thermal expansion coefficient of the shower head electrode SH, there is also a difference in the degree of deformation between the temperature control plate TCP and the shower head electrode SH. As an example, when the shower head electrode SH is expanded by a first length d1 in the second direction D2, the temperature control plate TCP may be expanded by a second length d2 that is longer than the first length d1. Accordingly, as shown in FIG. 4A, the displacement phenomenon of the thermal conductive pad TP may occur. In addition, the thermal conductive pad TP may be torn.

Referring to FIG. 4B, the gas hole may be blocked due to the displacement phenomenon of the thermal conductive pad TP, and the gas hole blockage may impede the smooth supply of gas into a chamber. As an example, when the thermal conductive pad TP is displaced by a third length d3, which is longer than the first length d1 and shorter than the second length d2, the gas hole may be blocked as shown in FIG. 4B. Due to the gas hole blockage, the pressure difference between upper and lower portions of the shower head electrode may increase, and as a result, an arching phenomenon that causes a strong impact inside the chamber may occur.

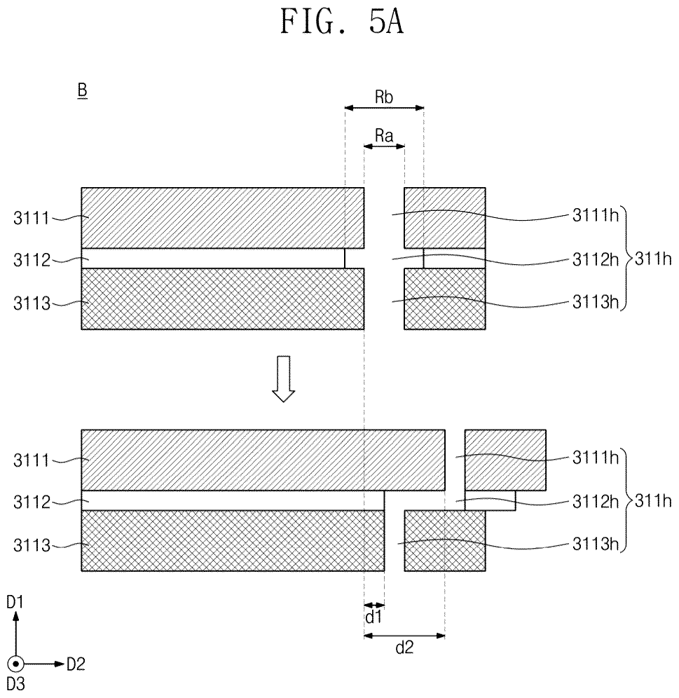

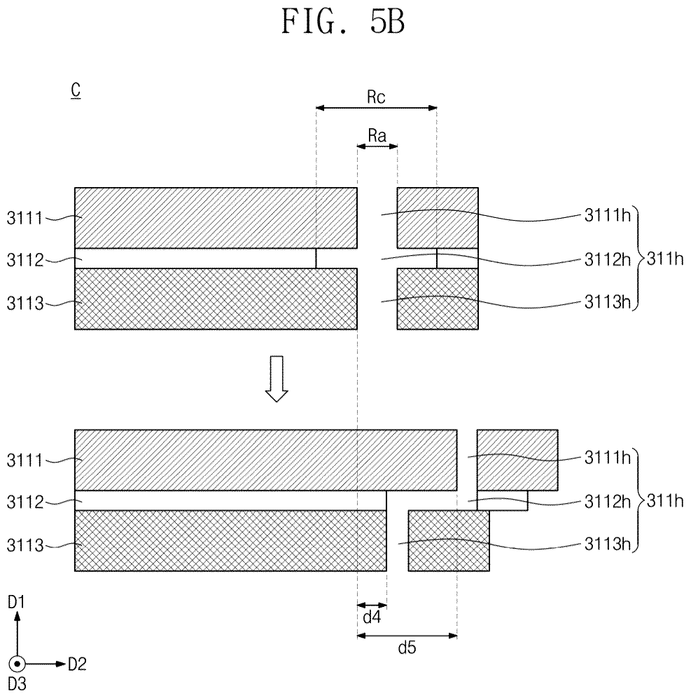

FIGS. 5A and 5B are views illustrating the opening of the thermal conductive pad according to an embodiment of the present disclosure. In detail, FIG. 5A is an enlarged cross-sectional view illustrating an area B of FIG. 1 according to an embodiment of the present disclosure. FIG. 5B is an enlarged cross-sectional view illustrating an area C of FIG. 1 according to an embodiment of the present disclosure. For the convenience of explanation, it is assumed that the thermal conductive pad 3112 is disposed between the first plate 3111 and the second plate 3113.

Referring to FIG. 5A, a length Rb in the second direction D2 of the opening 3112h of the thermal conductive pad 3112 may be longer than a length Ra in the second direction D2 of the first gas hole 3111h of the first plate 3111 and/or the second gas hole 3113h of the second plate 3113. Accordingly, although the first plate 3111 is expanded by a first length d1 and the second plate 3113 is expanded by a second length d2 due to the high-temperature process, the gas hole 311h may not be blocked. In other words, the gas hole blockage caused by the high-temperature process may be prevented.

Meanwhile, when the openings 3112h of the thermal conductive pad 3112 are all formed to be large, more empty space may be generated in the thermal conductive pad 3112, leading to a certain degree of reduction in the heat transfer performance. The thermal conductive pad 3112 according to an embodiment of the present disclosure may be configured with varying diameters of the openings, taking into account the degree of thermal expansion deformation depending on the location to minimize the reduction in heat transfer performance.

As an example, referring to FIGS. 5A and 5B, the deformation degree caused by the thermal expansion at high temperature in a portion of the first plate 3111, which is closer to a center of the first plate 3111, is relatively small, and the deformation degree caused by the thermal expansion at high temperature in a portion of the first plate 3111, which is far from the center of the first plate 3111, is relatively large. As an example, while the portion of the first plate 3111 in the area B may be expanded by the second length d2 at high temperature, the portion of the first plate 3111 in the area C may be expanded by a fifth length d5 longer than the second length d2 at high temperature.

Similarly, the deformation degree caused by the thermal expansion at high temperature in a portion of the second plate 3113, which is closer to a center of the second plate 3113, is relatively small, and the deformation degree caused by the thermal expansion at high temperature in a portion of the second plate 3113, which is far from the center of the second plate 3113, is relatively large. As an example, while the portion of the second plate 3113 in the area B may be expanded by the first length d1 at high temperature, the portion of the second plate 3113 in the area C may be expanded by a fourth length d4 longer than the first length d1 at high temperature.

In this case, even though the opening 3112h of the thermal conductive pad 3112 in the area B, which corresponds to the portion with relatively small degree of deformation due to thermal expansion at high temperature, is formed with relatively small diameter, the gas hole blockage phenomenon may be prevented. In addition, the opening 3112h of the thermal conductive pad 3112 in the area C, which corresponds to the portion with relatively large degree of deformation due to thermal expansion at high temperature, may have a relatively large diameter in order to prevent the gas hole blockage phenomenon. Accordingly, as shown in FIGS. 5A and 5B, a length Rb (e.g., diameter) of the opening 3112h in the area B that is closer to the center of the thermal conductive pad 3112 may be greater than a length Rc (e.g., diameter) of the opening 3112h in the area C that is far from the center of the thermal conductive pad 3112.

As described above, the deterioration in the heat transfer performance may be reduced and the gas hole blockage phenomenon caused by the pad displacement phenomenon may be prevented by setting the diameters for the openings to be different depending on their locations in the thermal conductive pad 3112.

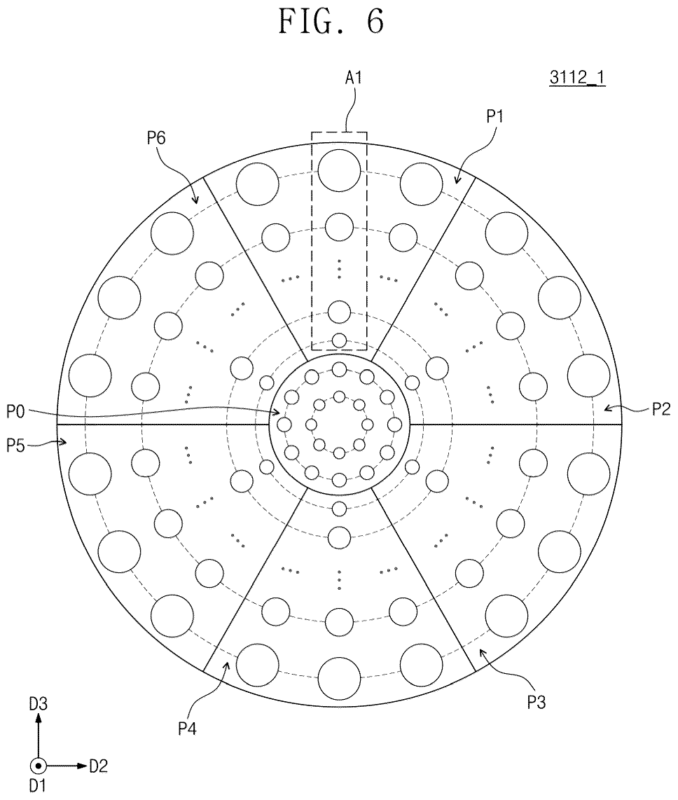

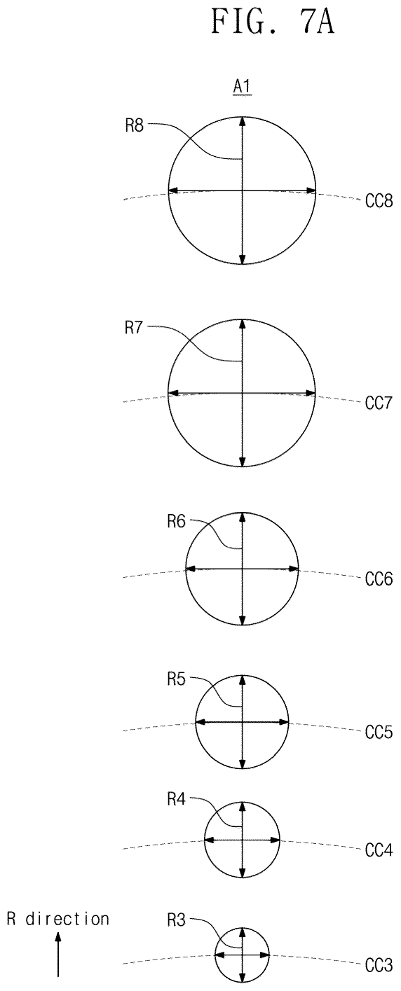

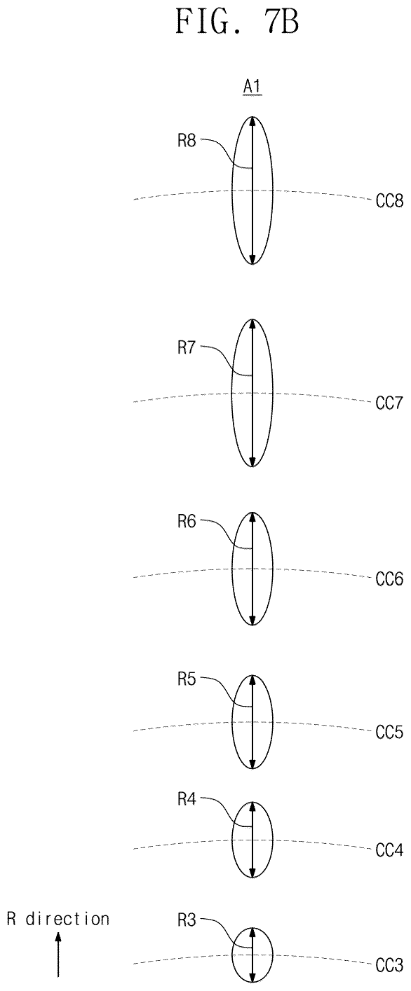

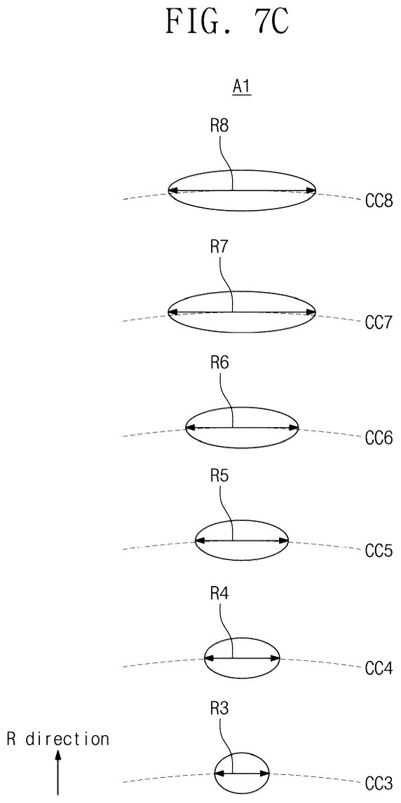

FIG. 6 is a plan view illustrating a thermal conductive pad 3112_1 according to an embodiment of the present disclosure. FIGS. 7A to 7C are views illustrating the opening of an area A1 of FIG. 6.

Referring to FIG. 6, the thermal conductive pad 3112_1 may have a disc shape corresponding to the shape of the second plate 3113 (refer to FIG. 3). In addition, the thermal conductive pad 3112_1 may include a plurality of pieces P0 to P6. That is, the pieces P0 to P6 may be physically coupled to each other to form one thermal conductive pad 3112_1.

According to an embodiment of the present disclosure, the openings of the thermal conductive pad 3112_1 may be formed to have different diameters depending on their locations to prevent the gas hole blockage phenomenon caused by the pad displacement and to reduce deterioration of the heat transfer performance.

As an example, referring to FIGS. 6 and 7A, the openings may be arranged in a concentric circular pattern with respect to a center of the thermal conductive pad 3112_1. In this case, the openings adjacent to the center of the thermal conductive pad 3112_1 may have a relatively small diameter, and the openings adjacent to an edge of the thermal conductive pad 3112_1 may have a relatively large diameter. That is, the diameter of the openings may gradually increase along a direction (hereinafter, referred to as R direction) away from the center of the thermal conductive pad 3112_1.

In detail, as shown in FIGS. 6 and 7A, the openings of the thermal conductive pad 31121 may be arranged along eight concentric circles. In this case, among openings of a first piece P1, openings corresponding to a third concentric circle CC3 are closest to the center of the thermal conductive pad 3112_1. Accordingly, since the deformation degree caused by the thermal expansion is the smallest, the openings corresponding to the third concentric circle CC3 may have the smallest diameter R3. In addition, among the openings of the first piece P1, openings corresponding to a fourth concentric circle CC4 are farther from the center of thermal conductive pad 3112_1 than the openings corresponding to the third concentric circle CC3. Therefore, a diameter R4 of the openings corresponding to the fourth concentric circle CC4 may be greater than the diameter R3 of the openings corresponding to the third concentric circle CC3. In this way, a diameter R5 of openings corresponding to a fifth concentric circle CC5 may be greater than the diameter R4 of the openings corresponding to the fourth concentric circle CC4, a diameter R6 of openings corresponding to a sixth concentric circle CC6 may be greater than the diameter R5 of the openings corresponding to the fifth concentric circle CC5, and a diameter R7 of openings corresponding to a seventh concentric circle CC7 may be greater than the diameter R6 of the openings corresponding to the sixth concentric circle CC6. Since the deformation degree caused by the thermal expansion is the largest, openings corresponding to an eighth concentric circle CC8 may have the largest diameter R8.

Meanwhile, FIG. 7A shows a structure in which the openings are arranged in the form of a circle. However, this is merely an example, and embodiments of the present disclosure are not limited thereto or thereby.

As an example, referring to FIG. 7B, openings may have an oval shape. In this case, a major axis of oval-shaped openings may gradually become longer along the R direction. As an example, a length R3 of a major axis of openings arranged along a third concentric circle CC3 may be the shortest, and a length R8 of a major axis of openings arranged along an eighth concentric circle CC8 may be the longest. In this case, the major axis of each opening may be formed along the R direction as its axis.

Referring to FIG. 7C, openings may have an oval shape, and a major axis of oval-shaped openings may gradually become longer along a direction perpendicular to the R direction. As an example, a length R3 of a major axis of openings arranged along a third concentric circle CC3 may be the shortest, and a length R8 of a major axis of openings arranged along an eighth concentric circle CC8 may be the longest. In this case, the major axis of each opening may be formed along the direction perpendicular to the R direction as its axis.

Meanwhile, the shape of each piece of the thermal conductive pad and the arrangement of each opening according to an embodiment of the present disclosure may be formed in various ways. Hereinafter, the shape of the thermal conductive pad according to various embodiments of the present disclosure will be described in more detail.

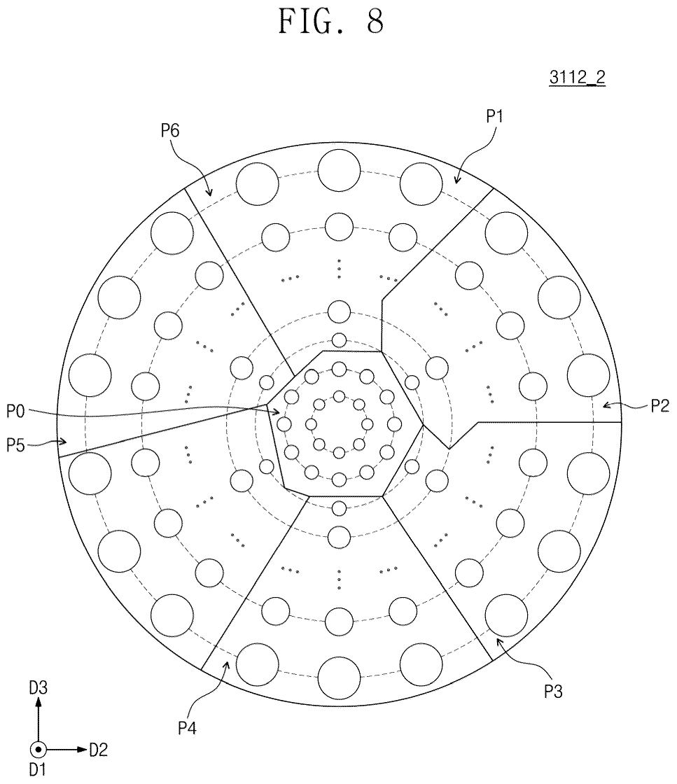

FIGS. 8 to 10 are plan views illustrating thermal conductive pads according to embodiments of the present disclosure. The thermal conductive pads shown in FIGS. 8 to 10 are similar to the thermal conductive pad shown in FIGS. 6 and 7A to 7C, and thus, repeated descriptions of the similar elements may be omitted.

In FIG. 6, the pieces of the thermal conductive pad have the same shape as each other. However, this is merely an example, and embodiments of the present disclosure are not limited thereto or thereby. As an example, as shown in FIG. 8, the thermal conductive pad 3112_2 may include a plurality of pieces P0 to P6, and each of the pieces P0 to P6 may be formed to have an irregular shape.

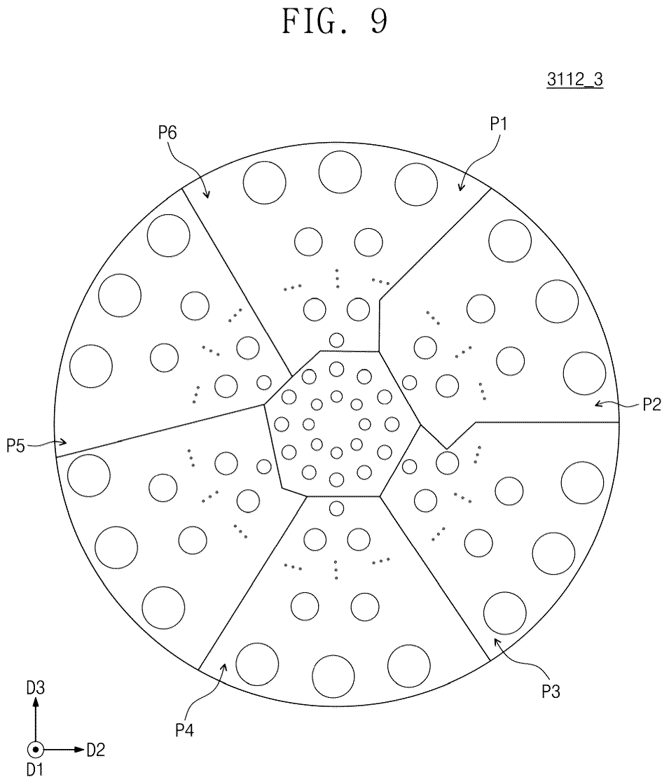

In addition, referring to FIG. 6, the openings of the thermal conductive pad are arranged along the concentric circle. However, this is merely an example, and embodiments of the present disclosure are not limited thereto or thereby. As an example, as shown in FIG. 9, openings of the thermal conductive pad 31123 may not be arranged along a concentric circle. In this case, the openings of the thermal conductive pad 3112_3 may be arranged in a variety of positions according to a position of a corresponding gas hole of a shower head electrode and/or a temperature control plate.

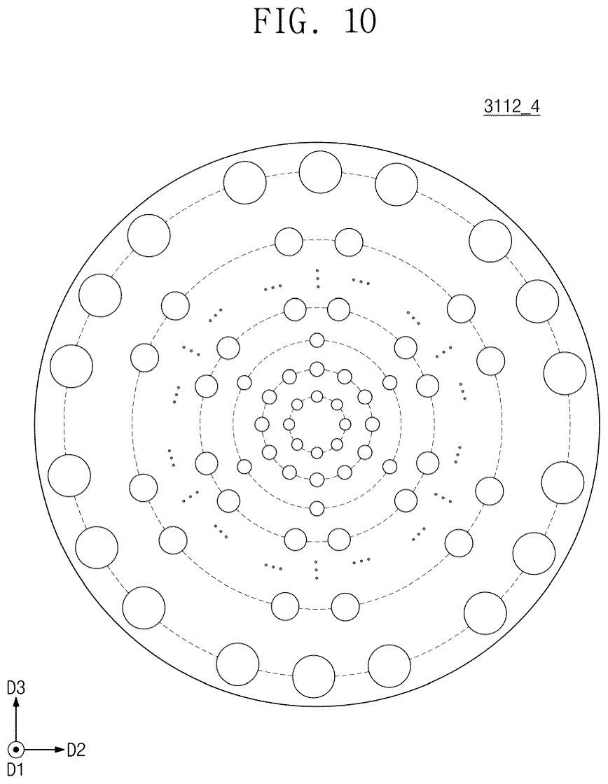

In addition, the thermal conductive pad shown in FIG. 6 includes the plural pieces. However, this is merely an example, and embodiments of the present disclosure are not limited thereto or thereby. As an example, as shown in FIG. 10, the thermal conductive pad 3112_4 may be implemented as a single pad that is not physically separated into multiple pieces.

Meanwhile, the thermal conductive pad according to embodiments of the present disclosure may be applied to semiconductor manufacturing equipment that is configured to perform various remote plasma methods. Hereinafter, an embodiment of the present disclosure applied to the remote plasma method will be described in detail.

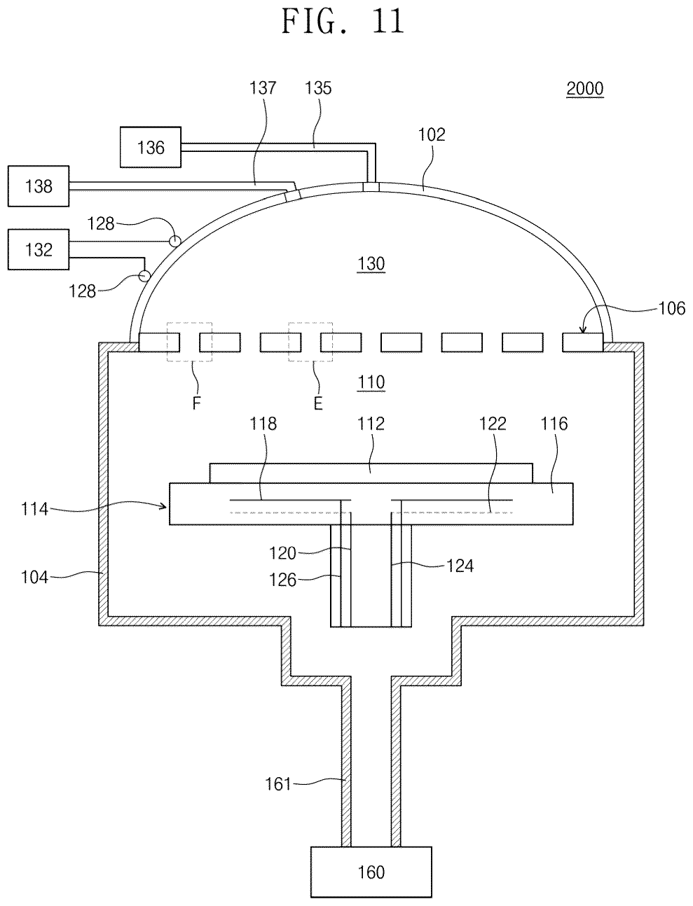

FIG. 11 is a view illustrating semiconductor manufacturing equipment 2000 according to an embodiment of the present disclosure.

Referring to FIG. 11, the semiconductor manufacturing equipment 2000 may include a remote plasma source 102, a reaction chamber 104, a wafer stage 114, and an exhaust unit 160 (e.g., an exhaust).

The remote plasma source 102 may be connected to the reaction chamber 104. As an example, the remote plasma source 102 may be fluidly coupled to the reaction chamber 104 via a shower head assembly 106.

According to an embodiment, the remote plasma source 102 may generate plasma in a plasma area 130 using an inductively coupled plasma (ICP) method. However, this is merely an example. According to an embodiment, the remote plasma source 102 may generate plasma in the plasma area 130 using a capacitive coupled plasma (CCP) method, a microwave method, etc.

The shower head assembly 106 may be disposed between the remote plasma source 102 and the reaction chamber 104. According to embodiments, the shower head assembly 106 may include an ion filter configured to filter ions to limit ion-bombardment damage to a wafer 112.

According to an embodiment, the shower head assembly 106 may include a thermal conductive pad. In this case, the thermal conductive pad may include a plurality of openings, and the openings may be arranged spaced apart from each other in the horizontal direction.

According to an embodiment, the opening of the thermal conductive pad may have a diameter greater than a diameter of a corresponding gas hole. As an example, when the thermal conductive pad is disposed between a first plate and a second plate, the opening of the thermal conductive pad may be greater than a corresponding gas hole of the first plate and/or a corresponding gas hole of the second plate. Therefore, the gas hole blockage phenomenon caused by the pad displacement in high temperature process may be prevented.

According to an embodiment, among the openings of the thermal conductive pad, a first opening may have a diameter different from a diameter of a second opening. As an example, the diameter of the second opening adjacent to an edge of the thermal conductive pad may be greater than the diameter of the first opening adjacent to a center of the thermal conductive pad. Accordingly, the deterioration of the heat transfer performance may be reduced, and the gas hole blockage phenomenon caused by the pad displacement in high temperature process may be prevented.

The reaction chamber 104 may provide a sealed space to perform deposition, etching, and cleaning processes on the wafer 112. The space of the reaction chamber 104, which may be provided to perform the deposition, etching, and cleaning processes, may be referred to as a reaction area 110. As an example, the reaction chamber 104 may include a metal material such as aluminum, stainless steel, etc.

The wafer stage 114 may be placed in the reaction chamber 104 to support the wafer 112. As an example, the wafer stage 114 may serve as a susceptor to support the wafer 112.

The wafer stage 114 may include an electrostatic chuck 116 to hold the wafer 112 thereon by an electrostatic attraction. As an example, the electrostatic chuck 116 may include one or more electrostatic clamping electrodes 118 embedded in a body thereof.

The one or more electrostatic clamping electrodes 118 may be disposed on the same plane or may be disposed on substantially the same plane. The electrostatic clamping electrodes 118 may be powered by a DC power source or a DC chucking voltage so that the wafer 112 is held on the electrostatic chuck 116 by the electrostatic attraction. According to embodiments, the power may be applied to the electrostatic clamping electrodes 118 via a first power line 120.

The electrostatic chuck 116 may further include one or more heating elements 122 embedded in the body of the electrostatic chuck 116. As an example, the one or more heating elements 122 may include a resistive heater. The one or more heating elements 122 may be disposed under the one or more electrostatic clamping electrodes 118. However, this is merely an example. According to an embodiment, the one or more heating elements 122 may be disposed above the electrostatic clamping electrodes 118.

The one or more heating elements 122 may be configured to heat the wafer 112. As an example, the one or more heating elements 122 may selectively control a temperature of the wafer 112. The power may be provided to the one or more heating elements 122 via a second power line 124.

The wafer stage 114 may further include a stem 126 connected to a lower portion of the electrostatic chuck 116. The stem 126 may serve as a column to support the electrostatic chuck 116. According to an embodiment, the stem 126 may be provided with a through hole defined therethrough to accommodate the first power line 120 and the second power line 124. In addition, according to an embodiment, the stem 126 may be configured to facilitate gas flow to a rear surface of the wafer 112. In addition, according to an embodiment, for precise temperature control of the wafer 112, a cooling gas, such as helium (He) gas, may be supplied between the electrostatic chuck 116 and the wafer 112.

The exhaust unit 160 may be connected to an exhaust port 161 installed at a lower portion of the reaction chamber 104 via an exhaust pipe.

According to an embodiment, a plasma processing device may further include a coil 128, a plasma generation controller 132, a source gas supply unit 136 (e.g., a source gas supply), and an equipment controller. In addition, according to an embodiment, the plasma processing device 100 may further include an additional gas supply unit 138 (e.g., an additionally gas supply).

The coil 128 may be placed around the remote plasma source 102. As an example, the remote plasma source 102 may include an outer wall in a dome shape, and the coil 128 may be disposed on the outer wall of the remote plasma source 102. However, this is merely an example, and the remote plasma source 102 may be implemented in various forms. In addition, the coil 128 may be placed around the remote plasma source 102 in a variety ways, including a direct-connection and/or an indirect-connection.

The plasma generation controller 132 may be electrically connected to the coil 128 to allow the plasma to be generated in the plasma area 130. As an example, the plasma generation controller 132 may include a power supply unit to supply power to the coil 128. As an example, the plasma generation controller 132 may provide a predetermined power to the coil 128 during the generation of plasma.

The source gas supply unit 136 may be connected to the remote plasma source 102 via a source gas supply line 135 to supply a source gas.

When the source gas supply unit 136 supplies the source gas to the remote plasma source 102, ions and/or radicals may be generated in the plasma area 130. The ion generated in the plasma area 130 may be filtered by an ion filter of the shower head assembly 106. As described above, the radicals generated in the plasma area 130 may be supplied to the wafer 112 in the reaction chamber 104 while limiting an ion-bombardment damage.

The additional gas supply unit 138 may supply one or more additional gases to the remote plasma source 102. Accordingly, the source gas may be mixed with the additional gases. The additional gases may support or stabilize steady-state plasma conditions within the remote plasma source 102 or may assist in ignition or extinguishment of the plasma.

As described above, the semiconductor manufacturing equipment 2000 according to an embodiment of the present disclosure may perform the remote plasma method. In this case, the semiconductor manufacturing equipment 2000 may include the thermal conductive pad, and the diameter of the opening of the thermal conductive pad may be greater than the diameter of the corresponding gas hole of the plate. Accordingly, the thermal conductive pad may be prevented from being displaced or torn in high temperature process.

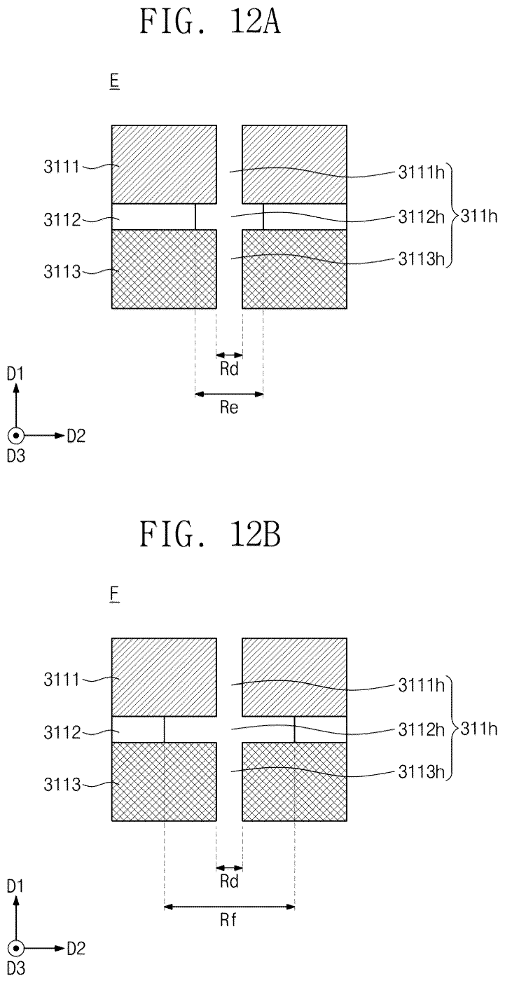

FIG. 12A is an enlarged cross-sectional view illustrating an area E of FIG. 11 according to an embodiment of the present disclosure. FIG. 12B is an enlarged cross-sectional view illustrating an area F of FIG. 11 according to an embodiment of the present disclosure. For the convenience of explanation, it is assumed that the thermal conductive pad 3112 is disposed between the first plate 3111 and the second plate 3113.

Referring to FIG. 12A, a length Re in the second direction D2 of an opening 3112h of the thermal conductive pad 3112 may be greater than a length Rd in the second direction D2 of a first gas hole 3111h of the first plate 3111 and/or a second gas hole 3113h of the second plate 3113. Accordingly, even though the first plate 3111 and/or the second plate 3113 are deformed due to thermal expansion caused by a high temperature process, the gas hole may be prevented from being blocked.

In addition, in order to minimize the reduction in the heat transfer performance while preventing the gas hole blockage, the thermal conductive pad 3112 may be configured with varying diameters of the openings depending on the location. As an example, referring to FIGS. 12A and 12B, a length (e.g., diameter Rf) of the opening 3112h in the area F far from the center of the thermal conductive pad 3112 may be greater than the length Re (e.g., diameter) of the opening 3112h in the area E closer to a center of the thermal conductive pad 3112.

As described above, as the diameter of the opening of the thermal conductive pad 3112 is set differently depending on the position of the opening of the thermal conductive pad 3112, deterioration of the heat transfer performance may be reduced, and the gas hole blockage caused by the pad displacement may be prevented.

Meanwhile, for the convenience of explanation, the thermal conductive pad of the shower head assembly is described as an example of embodiments of the present disclosure. However, this is merely an example, and embodiments of the present disclosure are not limited thereto or thereby. When a thermal conductive pad includes openings and the openings are subject to potential displacement or tearing due to high temperature, the thermal conductive pad according to an embodiment of the present disclosure may be applied.

While non-limiting example embodiments the present disclosure have been described with reference to accompanying drawings, it will be apparent to those of ordinary skill in the art that various changes and modifications may be made thereto without departing from the spirit and scope of the present disclosure.

What is claimed is:

1. A shower head assembly comprising:
a first plate including a first gas hole;
a second plate including a second gas hole that is fluidly coupled to the first gas hole; and
a thermal conductive pad between the first plate and the second plate, the thermal conductive pad including a first opening that fluidly couples the first gas hole to the second gas hole,
wherein the first opening has a diameter greater than at least one from among a diameter of the first gas hole and a diameter of the second gas hole.

2. The shower head assembly of claim 1, wherein the first plate further includes a third gas hole, the second plate further includes a fourth gas hole fluidly coupled to the third gas hole, and the thermal conductive pad further includes a second opening that fluidly couples the third gas hole to the fourth gas hole, and the diameter of the first opening is different from a diameter of the second opening.

3. The shower head assembly of claim 2, wherein the first opening is spaced apart from a center of the thermal conductive pad by a first distance, the second opening is spaced apart from the center of the thermal conductive pad by a second distance longer than the first distance, and the diameter of the first opening is smaller than the diameter of the second opening.

4. The shower head assembly of claim 3, wherein each of the first opening and the second opening has an oval shape.

5. The shower head assembly of claim 4, wherein the diameter of the first opening is a length of a major axis of the oval shape of the first opening, and the diameter of the second opening is a length of a major axis of the oval shape of the second opening, and
wherein the length of the major axis of the oval shape of the first opening is smaller than the length of the major axis of the oval shape of the second opening.

6. The shower head assembly of claim 1, wherein a material of the first plate has a thermal expansion coefficient that is different from a thermal expansion coefficient of a material of the second plate.

7. The shower head assembly of claim 6, wherein the first plate is a cooling plate, and the second plate is a shower head electrode.

8. A shower head assembly comprising:
a lower shower head; and
an upper shower head on the lower shower head, the lower shower head comprising:
a lower plate including lower plate gas holes; and
a support column extending upward from an upper surface of the lower plate and coupled to the upper shower head,
wherein the lower plate comprises:
a first plate including first gas holes;
a second plate including second gas holes that are fluidly coupled to the first gas holes, respectively; and
a thermal conductive pad between the first plate and the second plate, the thermal conductive pad including openings that fluidly couples the first gas holes to the second gas holes, respectively,
wherein each opening from among the openings has a diameter greater than a diameter of at least one from among a corresponding one of the first gas holes that is fluidly coupled to the opening and a corresponding one of the second gas holes that is fluidly coupled to the opening.

9. The shower head assembly of claim 8, wherein, in a plan view, the diameter of the openings varies based on a separation distance from a center of the thermal conductive pad.

10. The shower head assembly of claim 9, wherein, in the plan view, the diameter of the openings increases as a distance from the center of the thermal conductive pad increases.

11. The shower head assembly of claim 9, wherein each of the openings has an oval shape,
the diameter of the openings is a length of a major axis of the openings, and
the length of the major axis of the openings increases as a distance from the center of the thermal conductive pad increases.

12. Semiconductor manufacturing equipment comprising:
a shower head assembly comprising an upper shower head and a lower shower head, the lower shower head comprising:
a first plate including first gas holes;
a second plate including second gas holes that are fluidly coupled to the first gas holes, respectively; and
a thermal conductive pad between the first plate and the second plate, the thermal conductive pad including openings that fluidly couple the first gas holes to the second gas holes, respectively,
wherein each opening from among the openings has a diameter greater than a diameter at least one from among a corresponding first gas hole from among the first gas holes that is fluidly coupled to the opening and a corresponding second gas hole from among the second gas holes that is fluidly coupled to the opening.

13. The semiconductor manufacturing equipment of claim 12, wherein, in a plan view, the diameter of the openings varies based on a separation distance from a center of the thermal conductive pad.

14. The semiconductor manufacturing equipment of claim 13, wherein, in the plan view, the diameter of the openings increases as a distance from the center of the thermal conductive pad increases.

15. The semiconductor manufacturing equipment of claim 13, wherein each of the openings has an oval shape,
the diameter of the openings is a length of a major axis of the openings, and
the length of the major axis of the openings increases as a distance from the center of the thermal conductive pad increases.

16. The semiconductor manufacturing equipment of claim 12, wherein a material of the first plate has a thermal expansion coefficient that is different from a thermal expansion coefficient of a material of the second plate.

17. The semiconductor manufacturing equipment of claim 16, wherein the first plate is a cooling plate, and the second plate is a shower head electrode.

18. The semiconductor manufacturing equipment of claim 12, wherein the thermal conductive pad comprises pieces that have different shapes from each other.

19. The semiconductor manufacturing equipment of claim 18, wherein at least one piece from among the pieces includes:
a first opening, among the openings, spaced apart from a center of the thermal conductive pad by a first distance; and
a second opening, among the openings, spaced apart from the center of the thermal conductive pad by a second distance longer than the first distance, and the first opening has a diameter smaller than a diameter of the second opening.

20. The semiconductor manufacturing equipment of claim 12, further comprising a remote plasma source fluidly coupled to the shower head assembly and configured to generate a plasma.
